(19) United States
(12) Patent Application Publication
(10) Pub. No.: US 2026/0280756 A1
(43) Pub. Date: Sep. 17, 2026

(54) LDPC ENCODING WITH LONGER CODEWORD LENGTH AND LIFTING MATRIX DESIGN THEREOF FOR NEXT-GENERATION WLAN SYSTEMS

(71) Applicant: MEDIATEK INC., Hsinchu City (TW)

(72) Inventors: Shengquan HU, San Jose, CA (US); Jianhan LIU, San Jose, CA (US); Thomas Edward PARE, Jr., San Jose, CA (US)

(21) Appl. No.: 19/167,742

(22) PCT Filed: Aug. 30, 2024
(86) PCT No.: PCT/CN2024/115935

§ 371 Date: Sep. 22, 2025

Related U.S. Application Data
(60) Provisional application No. 63/535,825, filed on Aug. 31, 2023.
(60) Provisional application No. 63/581,307, filed on Sep. 8, 2023.

(51) Int. Cl. H04L 1/00; H03M 13/11

(52) U.S. Cl. CPC H04L 1/0057; H03M 13/1148

(57) ABSTRACT

Techniques pertaining to low-density parity-check (LDPC) encoding with longer codeword length and lifting matrix design thereof for next-generation wireless local area network (WLAN) systems in wireless communications are described. An apparatus (e.g., a station (STA)) encodes a plurality of bits with an enlarged codeword length which is longer than that of an existing LDPC parity check matrix. The apparatus then communicates with the encoded plurality of bits in a wireless communication system.

### CROSS REFERENCE TO RELATED PATENT APPLICATION

The present disclosure is part of a non-provisional patent application claiming the priority benefit of U.S. Provisional Patent Application No. 63/535,825 and 63/581,307, filed 31 Aug. 2023 and 8 Sep. 2023, respectively, the contents of which herein being incorporated by reference in their entirety.

### TECHNICAL FIELD

The present disclosure is generally related to wireless communications and, more particularly, to low-density parity-check (LDPC) encoding with longer codeword length and lifting matrix design thereof for next-generation wireless local area network (WLAN) systems in wireless communications.

### BACKGROUND

Unless otherwise indicated herein, approaches described in this section are not prior art to the claims listed below and are not admitted as prior art by inclusion in this section.

In wireless communications, LDPC encoding has been used in both cellular communications (e.g., 5th Generation (5G)/New Radio (NR)) in accordance with the 3rd Generation Partnership Project (3GPP) standards as well as Wi-Fi (or WiFi) and WLAN systems in accordance with the Institute of Electrical and Electronics Engineers (IEEE) 802.11 standards. In IEEE 802.11n/ac/ax/be, the coding rates are R=½, ⅔, ¾ and ⅚, with the codeword length L=648, 1296 (=2*648), and 1944 (=3*648). The LDPC parity check matrix is defined by a permutation matrix with a submatrix size Z=27, 54, 81. However, to enhance system performance and coverage range, higher LDPC coding rates and increased codeword lengths may be necessary but have yet to be defined. Therefore, there is a need for a solution of LDPC encoding with longer codeword length and lifting matrix design thereof for next-generation WLAN systems.

### SUMMARY

The following summary is illustrative only and is not intended to be limiting in any way. That is, the following summary is provided to introduce concepts, highlights, benefits and advantages of the novel and non-obvious techniques described herein. Select implementations are further described below in the detailed description. Thus, the following summary is not intended to identify essential features of the claimed subject matter, nor is it intended for use in determining the scope of the claimed subject matter.

An objective of the present disclosure is to provide schemes, concepts, designs, techniques, methods and apparatuses pertaining to LDPC encoding with longer codeword length and lifting matrix design thereof for next-generation WLAN systems in wireless communications. It is believed that implementations of various schemes proposed herein may extend the LDPC codeword length with L=2*1296 (=4* 648) and 2*1944(=6*648) used with corresponding to new parity check matrixes.

In one aspect, a method may involve encoding a plurality of bits with an enlarged codeword length which may be longer than that of an existing LDPC parity check matrix. The method may also involve communicating with the encoded plurality of bits in a wireless communication system.

In another aspect, an apparatus may include a transceiver configured to communicate wirelessly and a processor coupled to the transceiver. The processor may encode a plurality of bits with an enlarged codeword length which may be longer than that of an existing LDPC parity check matrix. The processor may also communicate with the encoded plurality of bits in a wireless communication system.

It is noteworthy that, although description provided herein may be in the context of certain radio access technologies, networks and network topologies such as, Wi-Fi, the proposed concepts, schemes and any variation(s)/derivative(s) thereof may be implemented in, for and by other types of radio access technologies, networks and network topologies such as, for example and without limitation, Bluetooth, ZigBee, 5^{th} Generation (5G)/New Radio (NR), Long-Term Evolution (LTE), LTE-Advanced, LTE-Advanced Pro, Internet-of-Things (IoT), Industrial IoT (IIoT) and narrowband IoT (NB-IoT). Thus, the scope of the present disclosure is not limited to the examples described herein.

### BRIEF DESCRIPTION OF THE DRAWINGS

The accompanying drawings are included to provide a further understanding of the disclosure and are incorporated in and constitute a part of the present disclosure. The drawings illustrate implementations of the disclosure and, together with the description, serve to explain the principles of the disclosure. It is appreciable that the drawings are not necessarily in scale as some components may be shown to be out of proportion than the size in actual implementation to clearly illustrate the concept of the present disclosure.

FIG. 1 is a diagram of an example network environment in which various solutions and schemes in accordance with the present disclosure may be implemented.

FIG. 2 is a diagram of an example design under a proposed scheme in accordance with the present disclosure.

FIG. 3 is a diagram of an example design under a proposed scheme in accordance with the present disclosure.

FIG. 4 is a diagram of an example design under a proposed scheme in accordance with the present disclosure.

FIG. 5 is a diagram of an example design under a proposed scheme in accordance with the present disclosure.

FIG. 6 is a diagram of an example design under a proposed scheme in accordance with the present disclosure.

FIG. 7 is a diagram of an example design under a proposed scheme in accordance with the present disclosure.

FIG. 8 is a diagram of an example scenario under a proposed scheme in accordance with the present disclosure.

FIG. 9 is a diagram of an example design under a proposed scheme in accordance with the present disclosure.

FIG. 10 is a diagram of an example design under a proposed scheme in accordance with the present disclosure.

FIG. 11 is a diagram of an example design under a proposed scheme in accordance with the present disclosure.

FIG. 12 is a diagram of an example design under a proposed scheme in accordance with the present disclosure.

FIG. 13 is a diagram of an example design under a proposed scheme in accordance with the present disclosure.

FIG. 14 is a diagram of an example design under a proposed scheme in accordance with the present disclosure.

FIG. 15 is a diagram of an example design under a proposed scheme in accordance with the present disclosure.

FIG. 16 is a diagram of an example design under a proposed scheme in accordance with the present disclosure.

FIG. 17 is a diagram of an example design under a proposed scheme in accordance with the present disclosure.

FIG. 18 is a block diagram of an example communication system in accordance with an implementation of the present disclosure.

FIG. 19 is a flowchart of an example process in accordance with an implementation of the present disclosure.

### DETAILED DESCRIPTION OF PREFERRED EMBODIMENTS

Detailed embodiments and implementations of the claimed subject matters are disclosed herein. However, it shall be understood that the disclosed embodiments and implementations are merely illustrative of the claimed subject matters which may be embodied in various forms. The present disclosure may, however, be embodied in many different forms and should not be construed as limited to the exemplary embodiments and implementations set forth herein. Rather, these exemplary embodiments and implementations are provided so that description of the present disclosure is thorough and complete and will fully convey the scope of the present disclosure to those skilled in the art. In the description below, details of well-known features and techniques may be omitted to avoid unnecessarily obscuring the presented embodiments and implementations.

### Overview

Implementations in accordance with the present disclosure relate to various techniques, methods, schemes and/or solutions pertaining to LDPC encoding with longer codeword length and lifting matrix design thereof for next-generation WLAN systems in wireless communications. According to the present disclosure, a number of possible solutions may be implemented separately or jointly. That is, although these possible solutions may be described below separately, two or more of these possible solutions may be implemented in one combination or another.

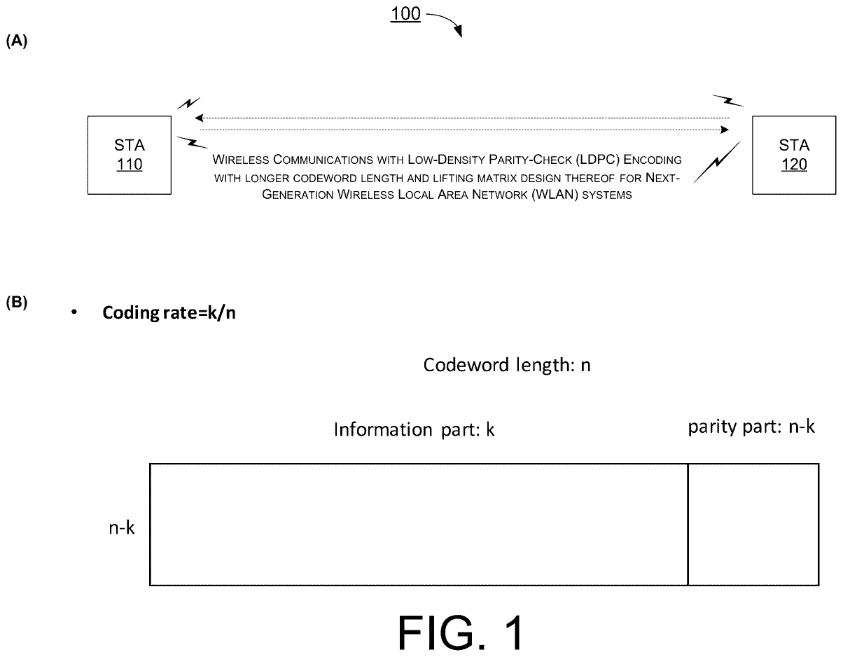

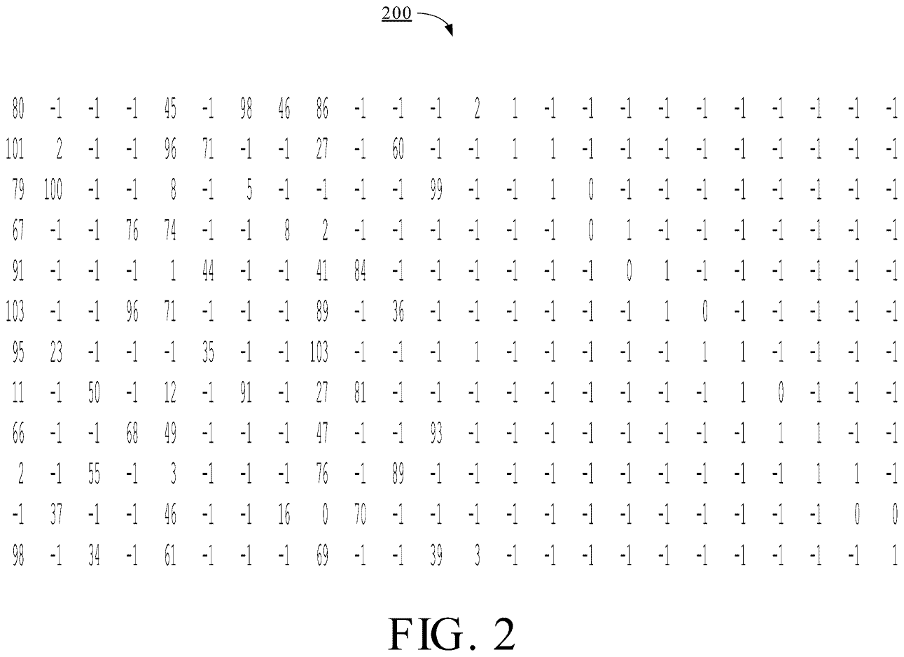

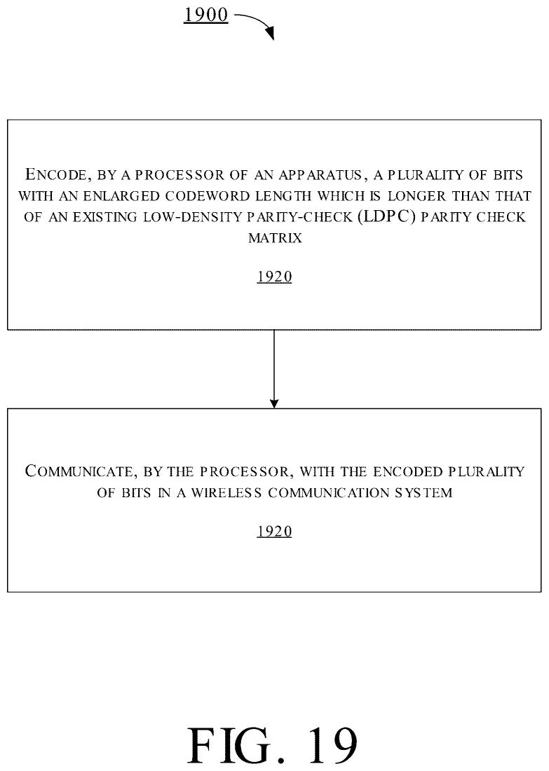

FIG. 1 illustrates an example network environment 100 in which various solutions and schemes in accordance with the present disclosure may be implemented. FIG. 2~FIG. 19 illustrate examples of implementation of various proposed schemes in network environment 100 in accordance with the present disclosure. The following description of various proposed schemes is provided with reference to FIG. 1~FIG. 19.

Referring to part (A) of FIG. 1, network environment 100 may involve at least a station (STA) 110 communicating wirelessly with a STA 120. Either of STA 110 and STA 120 may function as an access point (AP) STA or, alternatively, a non-AP STA. In some cases, STA 110 and STA 120 may be associated with a basic service set (BSS) in accordance with one or more IEEE 802.11 standards (e.g., IEEE 802.11be and future-developed standards). Each of STA 110 and STA 120 may be configured to communicate with each other by utilizing the LDPC encoding with longer codeword length and lifting matrix design thereof for next-generation WLAN systems in wireless communications in accordance with various proposed schemes described below. It is noteworthy that, while the various proposed schemes may be individually or separately described below, in actual implementations some or all of the proposed schemes may be utilized or otherwise implemented jointly. Of course, each of the proposed schemes may be utilized or otherwise implemented individually or separately.

Under current IEEE 802.11 specifications such as IEEE 802.11n/ac/ax/be, the LDPC coding rate R may be ½, ⅔, ¾ or ⅚. As for the codeword (K=L*R), the codeword length L may be 648, 1296 or 1944. Correspondingly, the parity matrix Z may be 27, 54 or 81. Referring to part (B) of FIG. 1, with a coding rate=k/n, the number of rows may be n−k, the number of columns of information bits may be k and the number of columns of parity bits may be n−k, corresponding to the following parameters: a codeword length=n, information part=k, and parity part=n−k. For instance, with R=¾ and Z=81, the codeword length=n=24*Z, the number of columns of information part=k=18*Z, and the number of columns of parity part=n−k=6*Z.

Under various proposed schemes in accordance with the present disclosure, a parity check for an existing LDPC in wireless communications in accordance with IEEE 802.11n/ac/ax/be may be defined by a submatrix size Z and a permutation value Pᵢⱼ in a parity check matrix H for a given element (i, j). Under the proposed scheme, for a codeword length L=1296 with Z=54, an enlarged submatrix with Z=2*54=108 for 2*1296 LDPC code may be defined, and the permutation value at a location (i, j) in a new LDPC parity check matrix for the enlarged codeword length 2*1296 may be 2*Pᵢⱼ+δᵢⱼ, with Pᵢⱼ being the value from an LDPC parity check matrix with L=1296 at location (i, j) and δᵢⱼ having a value of 0 or 1. Moreover, for a codeword length L=1944 with Z=81, an enlarged submatrix with Z=2*81=162 for 2*1944 LDPC code may be defined, and the permutation value at a location (i, j) in a new LDPC parity check matrix for the enlarged codeword length 2*1944 may be 2*Pᵢⱼ+δᵢⱼ, with Pᵢⱼ being the value from an LDPC parity check matrix with L=1944 at location (i, j) and δᵢⱼ having a value of 0 or 1.

FIG. 2 illustrates an example design 200 under a proposed scheme in accordance with the present disclosure. Design 200 may pertain to a parity check matrix for 2*1296 LDPC codes. Under the proposed scheme, the coding rate R=1/2, with Z=2*54=108. In design 200, “−1” denotes a Z×Z zero matrix, and “0” denotes a Z×Z identity matrix.

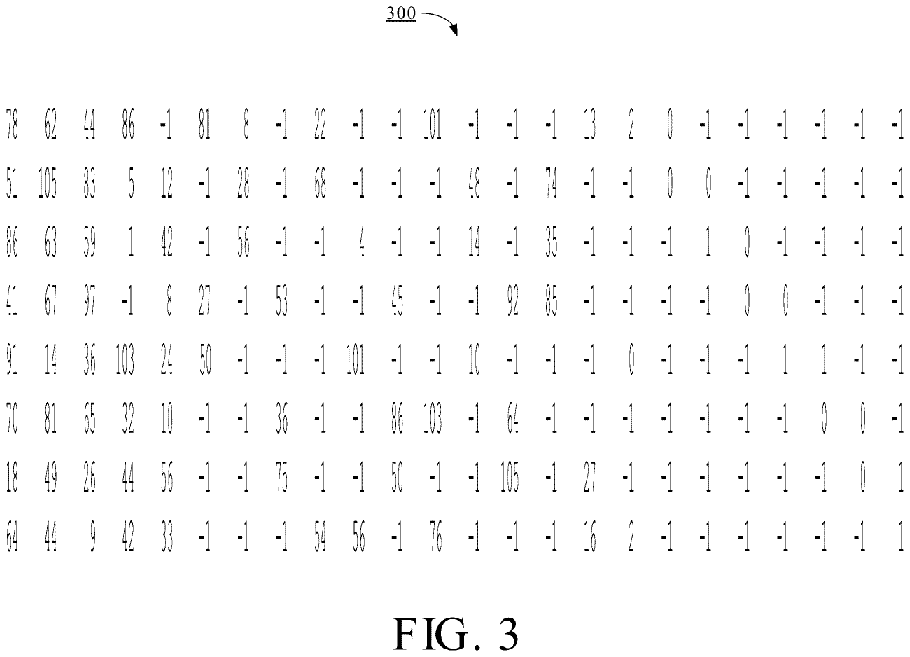

FIG. 3 illustrates an example design 300 under a proposed scheme in accordance with the present disclosure. Design 300 may pertain to a parity check matrix for 2*1296 LDPC codes. Under the proposed scheme, the coding rate R=⅔, with Z=2*54=108. In design 300, “−1” denotes a Z×Z zero matrix, and “0” denotes a Z×Z identity matrix.

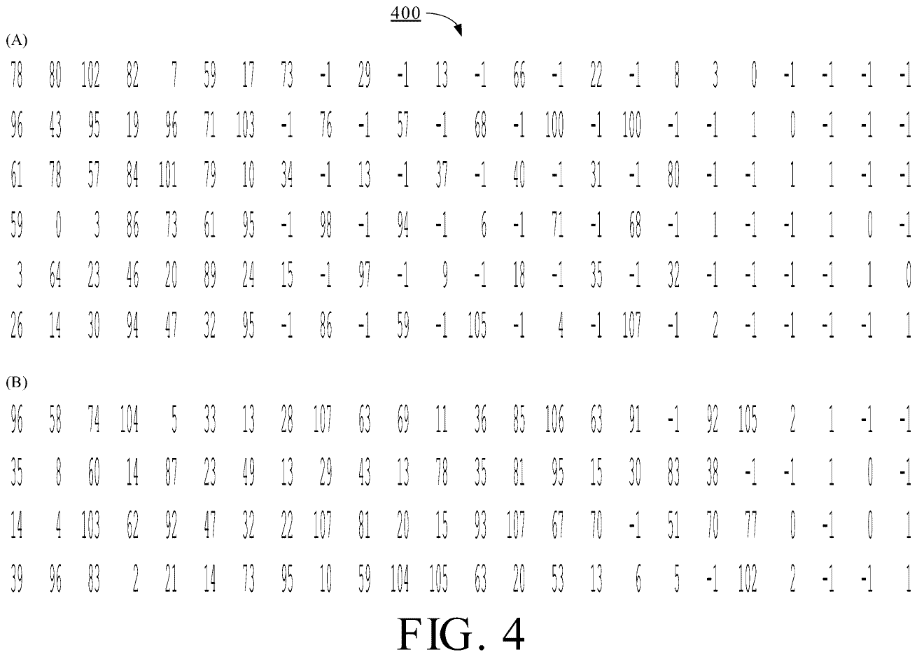

FIG. 4 illustrates an example design 400 under a proposed scheme in accordance with the present disclosure. Design 400 may pertain to a parity check matrix for 2*1296 LDPC codes. Under the proposed scheme, the coding rate R=¾, with Z=2*54=108, as shown in part (A) of FIG. 4. Alternatively, the coding rate R=⅚, with Z=2*54=108, as shown in part (B) of FIG. 4. In design 400, “−1” denotes a Z×Z zero matrix, and “0” denotes a Z×Z identity matrix.

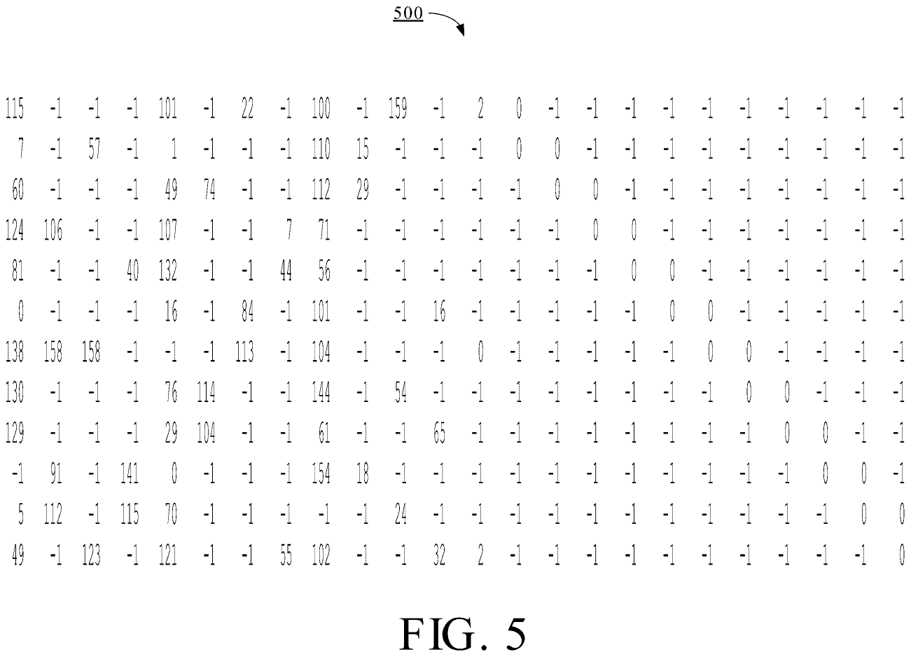

FIG. 5 illustrates an example design 500 under a proposed scheme in accordance with the present disclosure. Design 500 may pertain to a parity check matrix for 2*1944 LDPC codes. Under the proposed scheme, the coding rate R=½, with Z=2*81=162. In design 500, “−1” denotes a Z×Z zero matrix, and “0” denotes a Z×Z identity matrix.

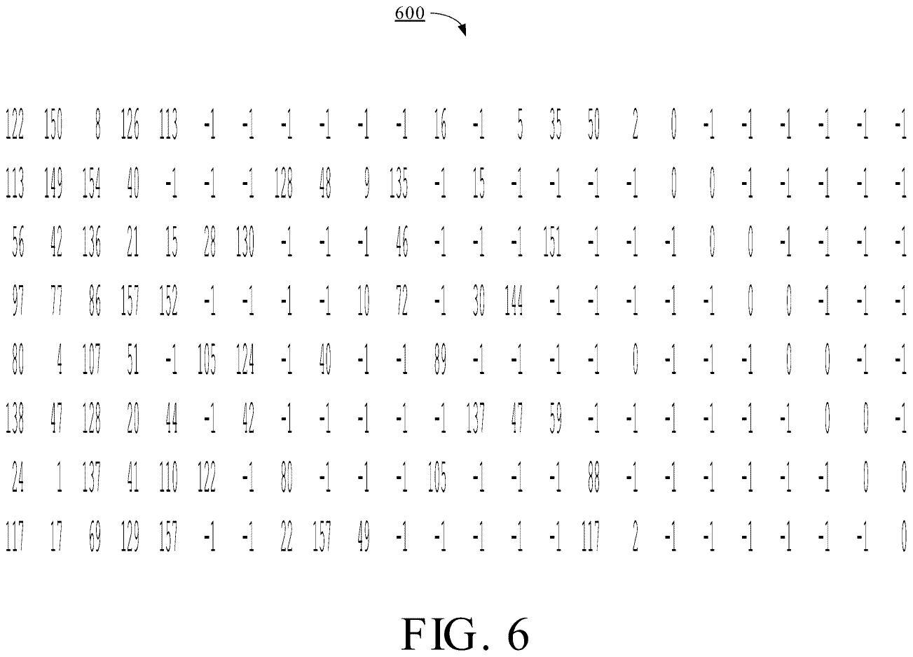

FIG. 6 illustrates an example design 600 under a proposed scheme in accordance with the present disclosure. Design 600 may pertain to a parity check matrix for 2*1944 LDPC codes. Under the proposed scheme, the coding rate R=⅔, with Z=2*81=162. In design 500, “−1” denotes a Z×Z zero matrix, and “0” denotes a Z×Z identity matrix.

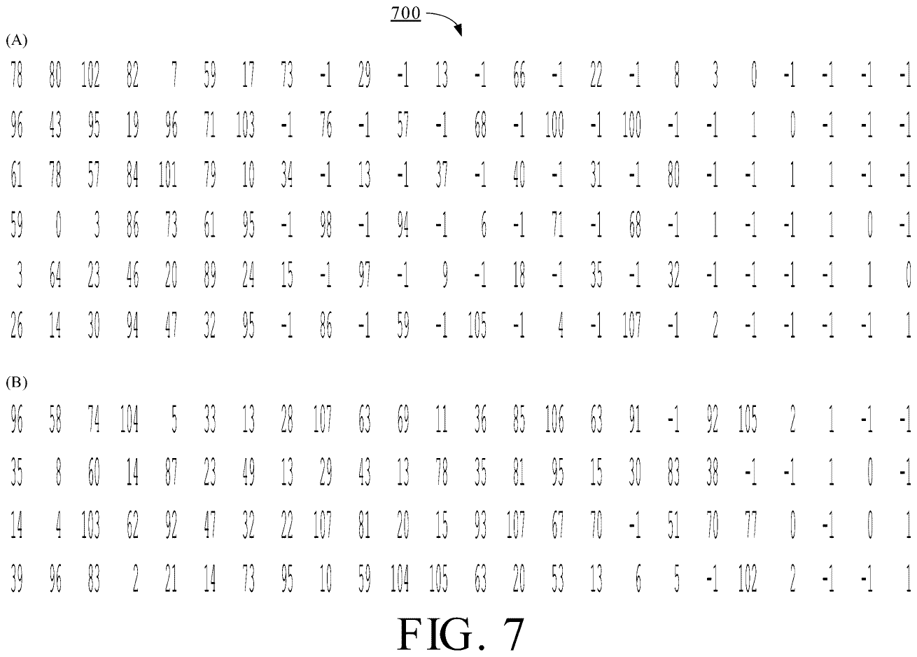

FIG. 7 illustrates an example design 700 under a proposed scheme in accordance with the present disclosure. Design 700 may pertain to a parity check matrix for 2*1944 LDPC codes. Under the proposed scheme, the coding rate R=¾, with Z=2*81=162, as shown in part (A) of FIG. 7. Alternatively, the coding rate R=⅚, with Z=2*81=162, as shown in part (B) of FIG. 7. In design 400, “−1” denotes a Z×Z zero matrix, and “0” denotes a Z×Z identity matrix.

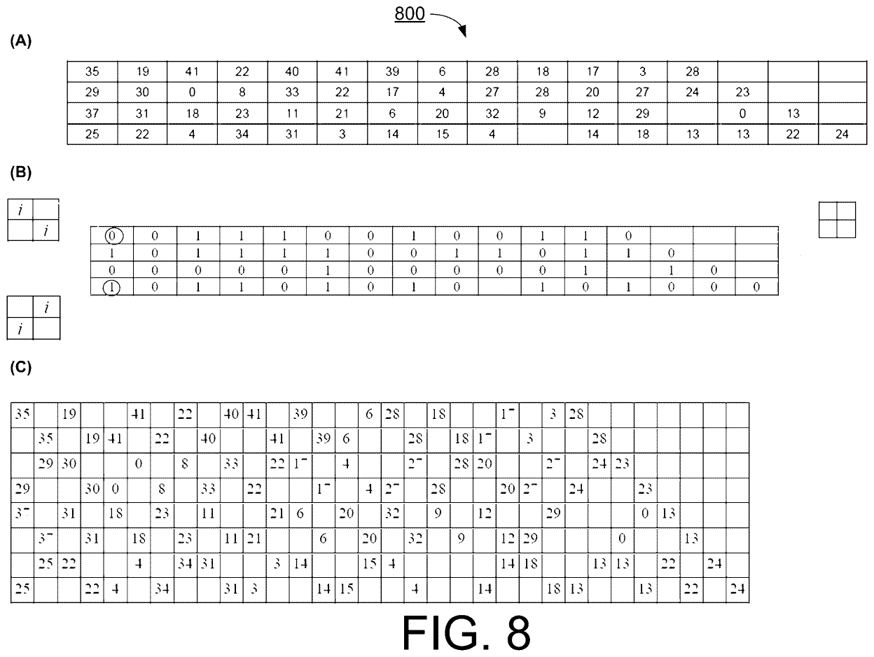

FIG. 8 illustrates an example scenario 800 under a proposed scheme in accordance with the present disclosure. Scenario 800 may pertain to enlargement of LDPC codeword length by using a lifting matrix. As defined in IEEE 802.11ad, the coding rate may be ½, ⅝, 3/4 or 13/16, and, for the parity matrix, Z=42 and H=336*672, 252*672, 168*672 or 126*672, respectively. As defined in IEEE 802.11ay, the coding rate may be ½, ⅝, ¾, 13/16, ⅞, ⅔ or ⅚, and for the parity matrix, Z=42 for a code length=672 and H=336*672, 252*672, 168*672, 126*672, 2Z*2Z with a lifting matrix, respectively, with the code length=2*672=1344. Under the proposed scheme, a lifting matrix similar to that defined in IEEE 802.11ay may be utilized to increase the LDPC codeword length.

Referring to part (A) of FIG. 8, with an original code rate R=¾LDPC parity check matrix, Z=42 with 168 rows×672 columns. Part (B) of FIG. 8 shows a lifting matrix for code rate of 3/4. Part (C) of FIG. 8 shows an LDPC code matrix for code rate of ¾ resulting from applying the lifting matrix of part (B) of FIG. 8 to the original LDPC parity check matrix of part (A) of FIG. 8. The resultant matrix may be double-sized and have 2*168 rows×2*672 column=336 rows×1344 columns.

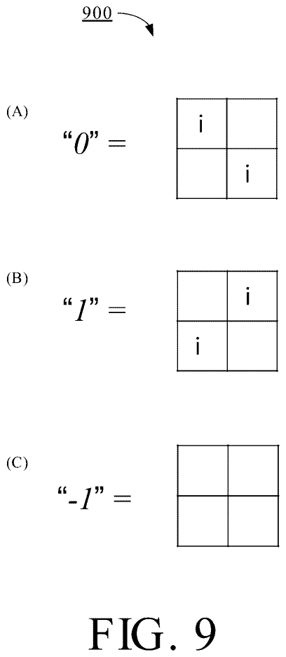

FIG. 9 illustrates an example design 900 under a proposed scheme in accordance with the present disclosure. Design 900 may pertain to increasing LDPC codeword length by one-step lifting. Under the proposed scheme, as shown in part (A) of FIG. 9, a non-blank element “0” in the lifting matrix may act on a Z×Z cyclic permutation matrix Pi in the LDPC parity check matrix to cause or result in a 2Z×2Z submatrix for two times (2×) enlargement of the codeword length, with “i” denoting the value of an original element of the Z×Z cyclic permutation matrix Pi which is duplicated and disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix.

Under the proposed scheme, as shown in part (B) of FIG. 9, a non-blank element “1” in the lifting matrix may act on a Z×Z cyclic permutation matrix Pi in the LDPC parity check matrix to cause or result in a 2Z×2Z submatrix for two times (2×) enlargement of the codeword length, with “i” denoting the value of an original element of the Z×Z cyclic permutation matrix Pi which is duplicated and disposed along a diagonal line from an upper-right corner to a lower-left corner of the 2Z−2Z submatrix, while a value “−1” is duplicated and disposed along an opposite diagonal line from an upper-left corner to a lower-right corner of the 2Z×2Z submatrix.

Under the proposed scheme, as shown in part (C) of FIG. 9, a non-blank element “−1” in the lifting matrix may act on a Z×Z cyclic permutation matrix Pi in the LDPC parity check matrix to cause or result in a 2Z×2Z submatrix for two times (2×) enlargement of the codeword length, with a value “×1” duplicated and disposed in the four corners of the 2Z×2Z submatrix.

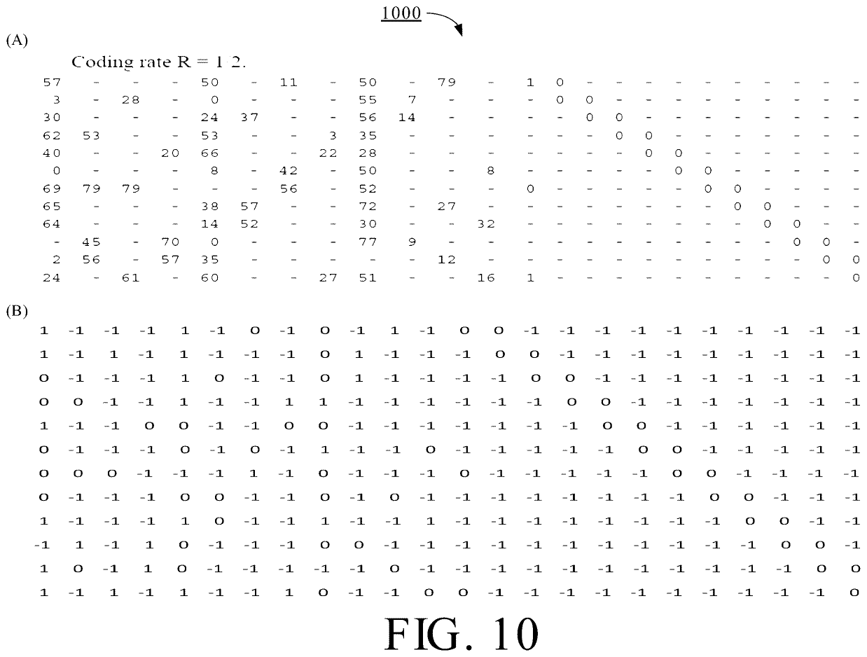

FIG. 10 illustrates an example design 1000 under a proposed scheme in accordance with the present disclosure. Design 1000 may pertain to an example of a lifting matrix design for L=2*1944, R=½. Part (A) of FIG. 10 shows an original parity check matrix for L=1944 may have a code rate R=½. Part (B) of FIG. 10 shows an example lifting matrix under the proposed scheme for L=2*1944 and R=½.

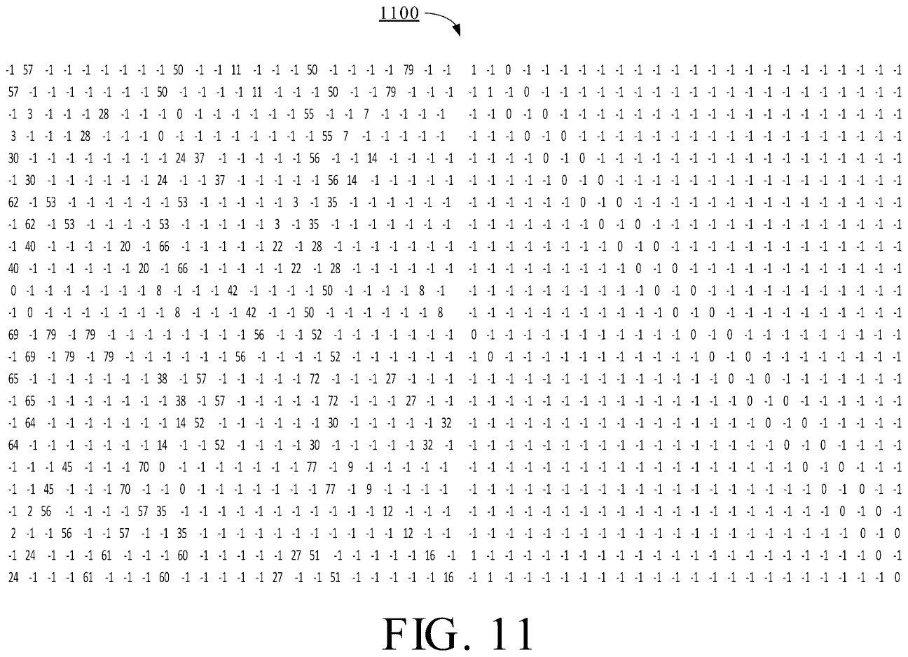

FIG. 11 illustrates an example design 1100 under a proposed scheme in accordance with the present disclosure. Design 1100 may pertain to an example of an LDPC matrix for a longer codeword of L=2*1944 with R=½, which may result from applying the lifting matrix of part (B) of FIG. 10 to the original parity check matrix of part (A) of FIG. 10.

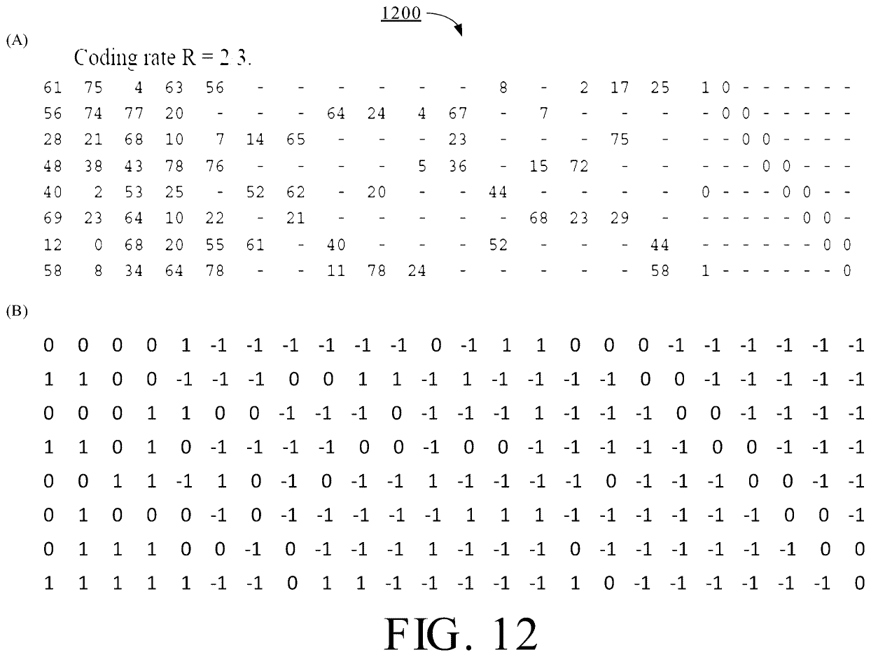

FIG. 12 illustrates an example design 1200 under a proposed scheme in accordance with the present disclosure. Design 1200 may pertain to an example of a lifting matrix design for L=2*1944, R=⅔. Part (A) of FIG. 12 shows an original parity check matrix for L=1944 may have a code rate R=⅔. Part (B) of FIG. 12 shows an example lifting matrix under the proposed scheme for L=2*1944 and R=⅔.

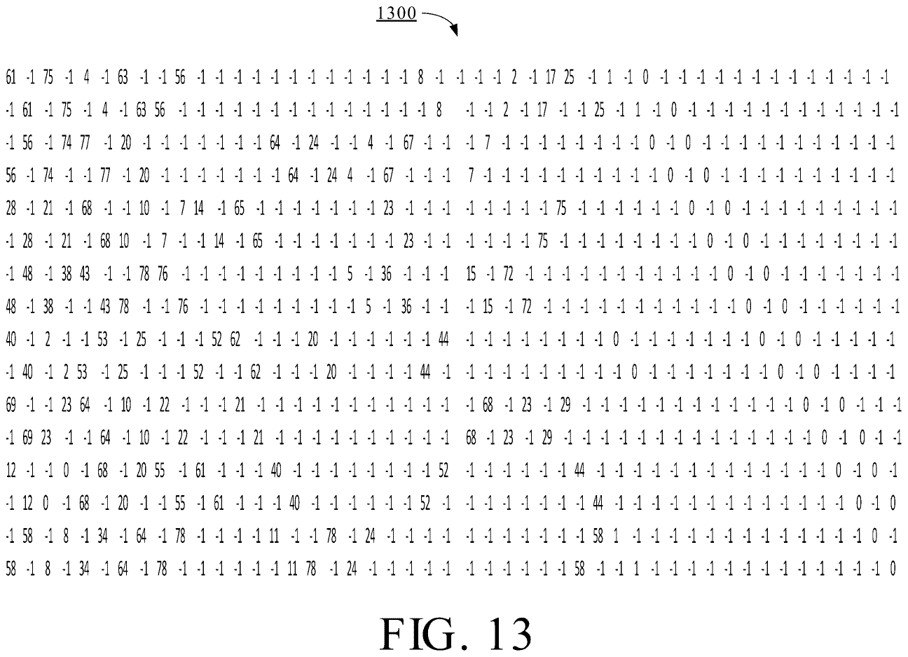

FIG. 13 illustrates an example design 1300 under a proposed scheme in accordance with the present disclosure. Design 1300 may pertain to an example of an LDPC matrix for a longer codeword of L=2*1944 with R=⅔, which may result from applying the lifting matrix of part (B) of FIG. 12 to the original parity check matrix of part (A) of FIG. 12.

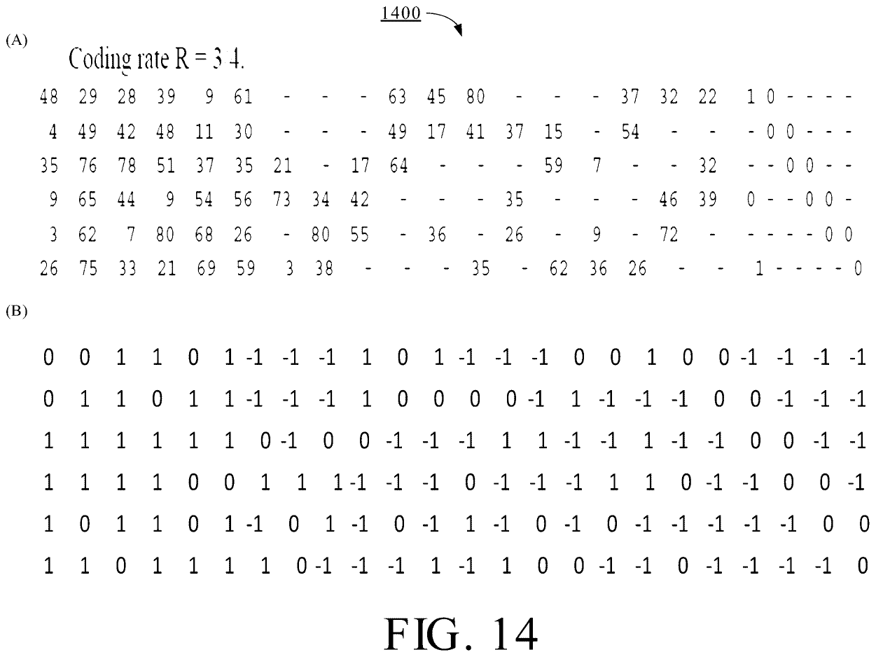

FIG. 14 illustrates an example design 1400 under a proposed scheme in accordance with the present disclosure. Design 1400 may pertain to an example of a lifting matrix design for L=2*1944, R=¾. Part (A) of FIG. 14 shows an original parity check matrix for L=1944 may have a code rate R=¾. Part (B) of FIG. 14 shows an example lifting matrix under the proposed scheme for L=2*1944 and R=¾.

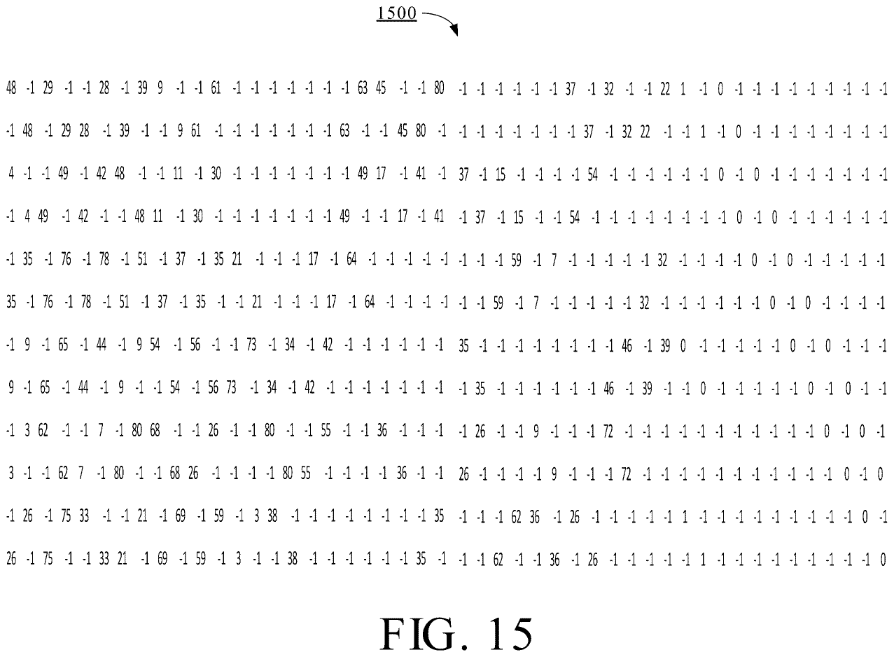

FIG. 15 illustrates an example design 1500 under a proposed scheme in accordance with the present disclosure. Design 1500 may pertain to an example of an LDPC matrix for a longer codeword of L=2*1944 with R=¾, which may result from applying the lifting matrix of part (B) of FIG. 14 to the original parity check matrix of part (A) of FIG. 14.

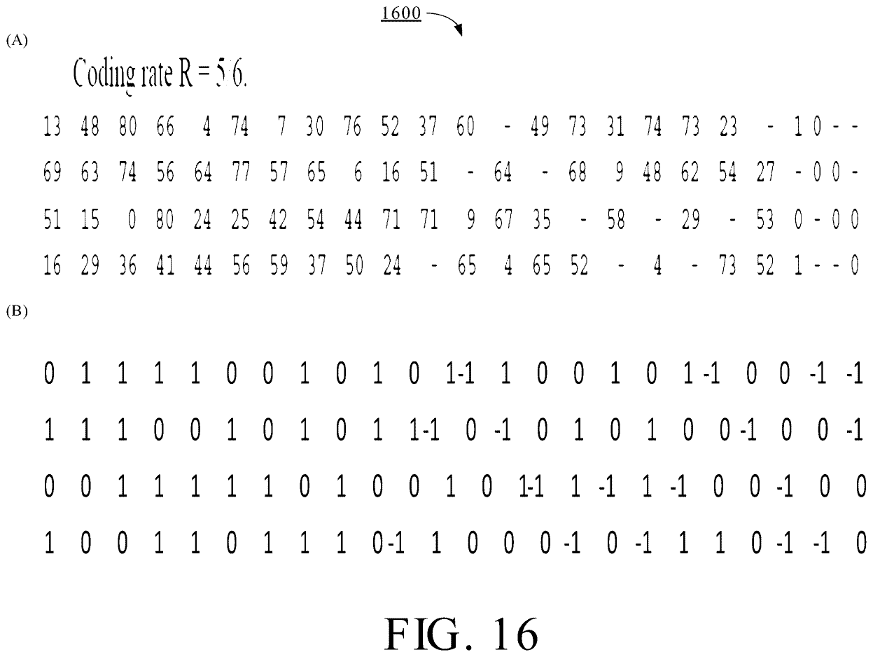

FIG. 16 illustrates an example design 1600 under a proposed scheme in accordance with the present disclosure. Design 1600 may pertain to an example of a lifting matrix design for L=2*1944, R=⅚. Part (A) of FIG. 16 shows an original parity check matrix for L=1944 may have a code rate R=¾. Part (B) of FIG. 16 shows an example lifting matrix under the proposed scheme for L=2*1944 and R=⅚.

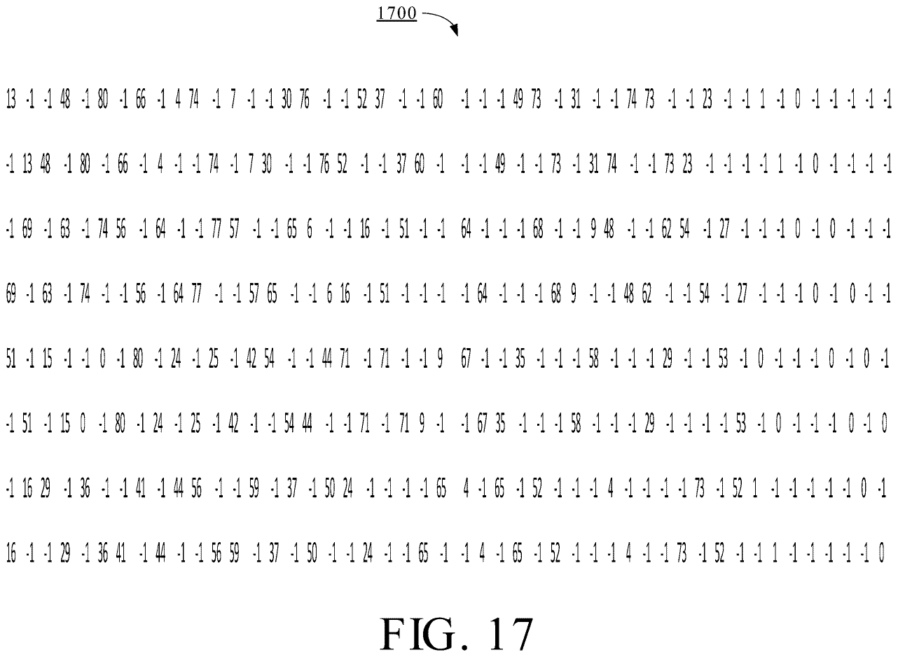

FIG. 17 illustrates an example design 1700 under a proposed scheme in accordance with the present disclosure. Design 1700 may pertain to an example of an LDPC matrix for a longer codeword of L=2*1944 with R=⅚, which may result from applying the lifting matrix of part (B) of FIG. 16 to the original parity check matrix of part (A) of FIG. 16.

### Illustrative Implementations

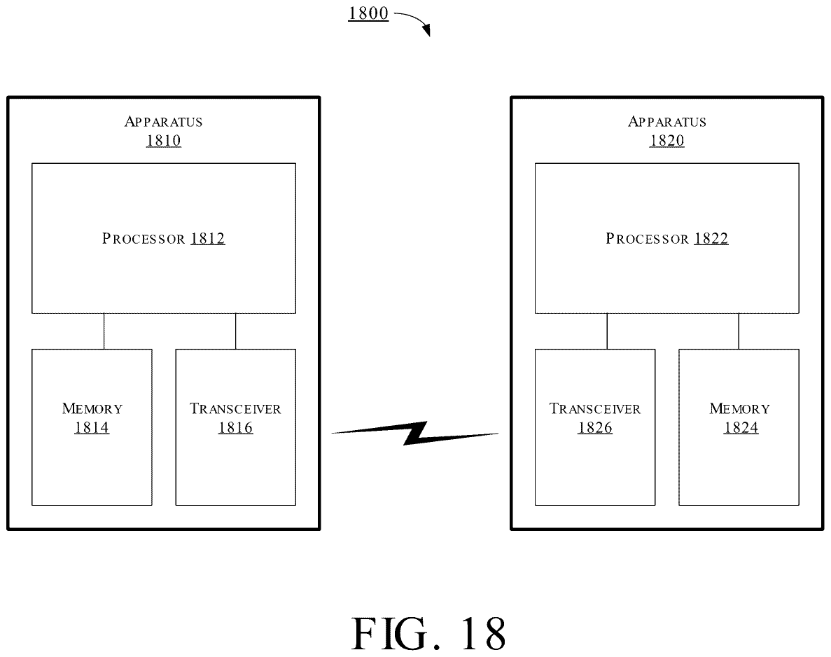

FIG. 18 illustrates an example system 1800 having at least an example apparatus 1810 and an example apparatus 1820 in accordance with an implementation of the present disclosure. Each of apparatus 1810 and apparatus 1820 may perform various functions to implement schemes, techniques, processes and methods described herein pertaining to LDPC encoding with longer codeword length and lifting matrix design thereof for next-generation WLAN systems in wireless communications including the various schemes described above with respect to various proposed designs, concepts, schemes, systems and methods described above as well as processes described below. For instance, apparatus 1810 may be implemented in STA 110 and apparatus 1820 may be implemented in STA 120, or vice versa.

Each of apparatus 1810 and apparatus 1820 may be a part of an electronic apparatus, which may be a non-AP STA or an AP STA, such as a portable or mobile apparatus, a wearable apparatus, a wireless communication apparatus or a computing apparatus. When implemented in a STA, each of apparatus 1810 and apparatus 1820 may be implemented in a smartphone, a smart watch, a personal digital assistant, a digital camera, or a computing equipment such as a tablet computer, a laptop computer or a notebook computer. Each of apparatus 1810 and apparatus 1820 may also be a part of a machine type apparatus, which may be an IoT apparatus such as an immobile or a stationary apparatus, a home apparatus, a wire communication apparatus or a computing apparatus. For instance, each of apparatus 1810 and apparatus 1820 may be implemented in a smart thermostat, a smart fridge, a smart door lock, a wireless speaker or a home control center. When implemented in or as a network apparatus, apparatus 1810 and/or apparatus 1820 may be implemented in a network node, such as an AP in a WLAN.

In some implementations, each of apparatus 1810 and apparatus 1820 may be implemented in the form of one or more integrated-circuit (IC) chips such as, for example and without limitation, one or more single-core processors, one or more multi-core processors, one or more reduced-instruction set computing (RISC) processors, or one or more complex-instruction-set-computing (CISC) processors. In the various schemes described above, each of apparatus 1810 and apparatus 1820 may be implemented in or as a STA or an AP. Each of apparatus 1810 and apparatus 1820 may include at least some of those components shown in FIG. 18 such as a processor 1812 and a processor 1822, respectively, for example. Each of apparatus 1810 and apparatus 1820 may further include one or more other components not pertinent to the proposed scheme of the present disclosure (e.g., internal power supply, display device and/or user interface device), and, thus, such component(s) of apparatus 1810 and apparatus 1820 are neither shown in FIG. 18 nor described below in the interest of simplicity and brevity.

In one aspect, each of processor 1812 and processor 1822 may be implemented in the form of one or more single-core processors, one or more multi-core processors, one or more RISC processors or one or more CISC processors. That is, even though a singular term “a processor” is used herein to refer to processor 1812 and processor 1822, each of processor 1812 and processor 1822 may include multiple processors in some implementations and a single processor in other implementations in accordance with the present disclosure. In another aspect, each of processor 1812 and processor 1822 may be implemented in the form of hardware (and, optionally, firmware) with electronic components including, for example and without limitation, one or more transistors, one or more diodes, one or more capacitors, one or more resistors, one or more inductors, one or more memristors and/or one or more varactors that are configured and arranged to achieve specific purposes in accordance with the present disclosure. In other words, in at least some implementations, each of processor 1812 and processor 1822 is a special-purpose machine specifically designed, arranged and configured to perform specific tasks including those pertaining to LDPC encoding with longer codeword length and lifting matrix design thereof for next-generation WLAN systems in wireless communications in accordance with various implementations of the present disclosure.

In some implementations, apparatus 1810 may also include a transceiver 1816 coupled to processor 1812. Transceiver 1816 may include a transmitter capable of wirelessly transmitting and a receiver capable of wirelessly receiving data. In some implementations, apparatus 1820 may also include a transceiver 1826 coupled to processor 1822. Transceiver 1826 may include a transmitter capable of wirelessly transmitting and a receiver capable of wirelessly receiving data. It is noteworthy that, although transceiver 1816 and transceiver 1826 are illustrated as being external to and separate from processor 1812 and processor 1822, respectively, in some implementations, transceiver 1816 may be an integral part of processor 1812 as a system on chip (SoC), and transceiver 1826 may be an integral part of processor 1822 as a SoC.

In some implementations, apparatus 1810 may further include a memory 1814 coupled to processor 1812 and capable of being accessed by processor 1812 and storing data therein. In some implementations, apparatus 1820 may further include a memory 1824 coupled to processor 1822 and capable of being accessed by processor 1822 and storing data therein. Each of memory 1814 and memory 1824 may include a type of random-access memory (RAM) such as dynamic RAM (DRAM), static RAM (SRAM), thyristor RAM (T-RAM) and/or zero-capacitor RAM (Z-RAM). Alternatively, or additionally, each of memory 1814 and memory 1824 may include a type of read-only memory (ROM) such as mask ROM, programmable ROM (PROM), erasable programmable ROM (EPROM) and/or electrically erasable programmable ROM (EEPROM). Alternatively, or additionally, each of memory 1814 and memory 1824 may include a type of non-volatile random-access memory (NVRAM) such as flash memory, solid-state memory, ferroelectric RAM (FeRAM), magnetoresistive RAM (MRAM) and/or phase-change memory.

Each of apparatus 1810 and apparatus 1820 may be a communication entity capable of communicating with each other using various proposed schemes in accordance with the present disclosure. For illustrative purposes and without limitation, a description of capabilities of apparatus 1810, as STA 110, and apparatus 1820, as STA 120, is provided below in the context of example process 1900. It is noteworthy that, although a detailed description of capabilities, functionalities and/or technical features of apparatus 1820 is provided below, the same may be applied to apparatus 1810 although a detailed description thereof is not provided solely in the interest of brevity. It is also noteworthy that, although the example implementations described below are provided in the context of WLAN, the same may be implemented in other types of networks.

### Illustrative Processes

FIG. 19 illustrates an example process 1900 in accordance with an implementation of the present disclosure. Process 1900 may represent an aspect of implementing various proposed designs, concepts, schemes, systems and methods described above. More specifically, process 1900 may represent an aspect of the proposed concepts and schemes pertaining to LDPC encoding with longer codeword length and lifting matrix design thereof for next-generation WLAN systems in wireless communications in accordance with the present disclosure. Process 1900 may include one or more operations, actions, or functions as illustrated by one or more of blocks 1910 and 1920. Although illustrated as discrete blocks, various blocks of process 1900 may be divided into additional blocks, combined into fewer blocks, or eliminated, depending on the desired implementation. Moreover, the blocks/sub-blocks of process 1900 may be executed in the order shown in FIG. 19 or, alternatively, in a different order. Furthermore, one or more of the blocks/sub-blocks of process 1900 may be executed repeatedly or iteratively. Process 1900 may be implemented by or in apparatus 1810 and apparatus 1820 as well as any variations thereof. Solely for illustrative purposes and without limiting the scope, process 1900 is described below in the context of apparatus 1810 implemented in or as STA 110 functioning as a non-AP STA or an AP STA and apparatus 1820 implemented in or as STA 120 functioning as an AP STA or a non-AP STA of a wireless network such as a WLAN in network environment 100 in accordance with one or more of IEEE 802.11 standards. Process 1900 may begin at block 1910.

At 1910, process 1900 may involve processor 1812 of apparatus 1810 encoding a plurality of bits with an enlarged codeword length which may be longer than that of an existing LDPC parity check matrix. Process 1900 may proceed from 1910 to 1920.

At 1920, process 1900 may involve processor 1812 communicating, via transceiver 1816, with the encoded plurality of bits in a wireless communication system (e.g., by transmitting the encoded bits to apparatus 1820).

In some implementations, in encoding, process 1900 may involve processor 1812 increasing a codeword length L by two times (2×) such that: (a) for L=1296, the enlarged codeword length=2*1296=2592, and (b) for L=1944, the enlarged codeword length=2*1944=3888.

In some implementations, for L=1296 with a submatrix size Z=54, in encoding, process 1900 may further involve processor 1812 encoding with an enlarged submatrix size of 2*54=108 corresponding to a new LDPC parity check matrix with the enlarged codeword length of 2*1296. In some implementations, a permutation value at a location (i, j) in a new LDPC parity check matrix for the enlarged codeword length 2*1296 may be 2*Pᵢⱼ+δᵢⱼ, with Pᵢⱼ denoting a value from the existing LDPC parity check matrix with L=1296 at a location (i, j) and with δᵢⱼ having a value of 0 or 1.

In some implementations, for L=1944 with a submatrix size Z=81, in encoding, process 1900 may further involve processor 1812 encoding with an enlarged submatrix size of 2*81=162 corresponding to a new LDPC parity check matrix with the enlarged codeword length of 2*1944. In some implementations, a permutation value at a location (i, j) in a new LDPC parity check matrix for the enlarged codeword length 2*1944 may be 2*Pᵢⱼ+δᵢⱼ, with Pᵢⱼ denoting a value from the existing LDPC parity check matrix with L=1944 at a location (i, j) and with δᵢⱼ having a value of 0 or 1.

In some implementations, responsive to the enlarged codeword length=2*1296, in encoding, process 1900 may involve processor 1812 encoding using a coding rate R=½ with a submatrix size Z=2*54=108.

In some implementations, responsive to the enlarged codeword length=2*1296, in encoding, process 1900 may involve processor 1812 encoding using a coding rate R=⅔ with a submatrix size Z=2*54=108.

In some implementations, responsive to the enlarged codeword length=2*1296, in encoding, process 1900 may involve processor 1812 encoding using a coding rate R=¾ with a submatrix size Z=2*54=108.

In some implementations, responsive to the enlarged codeword length=2*1296, in encoding, process 1900 may involve processor 1812 encoding using a coding rate R=⅚ with a submatrix size Z=2*54=108.

In some implementations, responsive to the enlarged codeword length=2*1944, in encoding, process 1900 may involve processor 1812 encoding using a coding rate R=½ with a submatrix size Z=2*81=162.

In some implementations, responsive to the enlarged codeword length=2*1944, in encoding, process 1900 may involve processor 1812 encoding using a coding rate R=⅔ with a submatrix size Z=2*81=162.

In some implementations, responsive to the enlarged codeword length=2*1944, in encoding, process 1900 may involve processor 1812 encoding using a coding rate R=3/4 with a submatrix size Z=2*81=162.

In some implementations, responsive to the enlarged codeword length=2*1944, in encoding, process 1900 may involve processor 1812 encoding using a coding rate R=⅚ with a submatrix size Z=2*81=162.

In some implementations, responsive to the enlarged codeword length=2*1944, in encoding, process 1900 may involve processor 1812 encoding using a coding rate R=½, ⅔, ¾ or ⅚ and applying a lifting matrix to the existing LDPC parity check matrix, with each element in the lifting matrix acting on a Z×Z cyclic permutation matrix Pi at a same location in an LDPC parity check matrix creating a submatrix of size 2Z×2Z such that: (a) a non-blank element “0” in the lifting matrix acting on the Z×Z cyclic permutation matrix Pi at the same location creates the 2Z×2Z submatrix with a value of an original element of the Z×Z cyclic permutation matrix disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix; (b) a non-blank element “1” in the lifting matrix acting on the Z×Z cyclic permutation matrix Pi at the same location creates the 2Z×2Z submatrix with the value of the original element of the Z×Z cyclic permutation matrix disposed along another diagonal line from an upper-right corner to a lower-left corner of the 2Z×2Z submatrix, while the value “−1” is duplicated and disposed along an opposite diagonal line from an upper-left corner to a lower-right corner of the 2Z×2Z submatrix; and (c) a non-blank element “−1” in the lifting matrix acting on the Z×Z cyclic permutation matrix Pi at the same location creates the 2Z×2Z submatrix with the value “−1” duplicated and disposed in the four corners of the 2Z×2Z submatrix.

Additional Notes The herein-described subject matter sometimes illustrates different components contained within, or connected with, different other components. It is to be understood that such depicted architectures are merely examples, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

Further, with respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

Moreover, it will be understood by those skilled in the art that, in general, terms used herein, and especially in the appended claims, e.g., bodies of the appended claims, are generally intended as “open” terms, e.g., the term “including” should be interpreted as “including but not limited to,” the term “having” should be interpreted as “having at least,” the term “includes” should be interpreted as “includes but is not limited to,” etc. It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to implementations containing only one such recitation, even when the same claim includes the introductory phrases “one or more” or “at least one” and indefinite articles such as “a” or “an,” e.g., “a” and/or “an” should be interpreted to mean “at least one” or “one or more;” the same holds true for the use of definite articles used to introduce claim recitations. In addition, even if a specific number of an introduced claim recitation is explicitly recited, those skilled in the art will recognize that such recitation should be interpreted to mean at least the recited number, e.g., the bare recitation of “two recitations,” without other modifiers, means at least two recitations, or two or more recitations. Furthermore, in those instances where a convention analogous to “at least one of A, B, and C, etc.” is used, in general such a construction is intended in the sense one having skill in the art would understand the convention, e.g., “a system having at least one of A, B, and C” would include but not be limited to systems that have A alone, B alone, C alone, A and B together, A and C together, B and C together, and/or A, B, and C together, etc. In those instances where a convention analogous to “at least one of A, B, or C, etc.” is used, in general such a construction is intended in the sense one having skill in the art would understand the convention, e.g., “a system having at least one of A, B, or C” would include but not be limited to systems that have A alone, B alone, C alone, A and B together, A and C together, B and C together, and/or A, B, and C together, etc. It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

From the foregoing, it will be appreciated that various implementations of the present disclosure have been described herein for purposes of illustration, and that various modifications may be made without departing from the scope and spirit of the present disclosure. Accordingly, the various implementations disclosed herein are not intended to be limiting, with the true scope and spirit being indicated by the following claims.

What is claimed is:

1. A method, comprising:
encoding, by a processor of an apparatus, a plurality of bits with an enlarged codeword length which is longer than that of an existing low-density parity-check (LDPC) parity check matrix; and
communicating, by the processor, with the encoded plurality of bits in a wireless communication system.

2. The method of claim 1, wherein the encoding comprises increasing a codeword length L by two times (2×) such that:
for L=1296, the enlarged codeword length=2*1296=2592, and for L=1944, the enlarged codeword length=2*1944=3888.

3. The method of claim 2, wherein, for L=1296 with a submatrix size Z=54, the encoding further comprises encoding with an enlarged submatrix size of 2*54=108 corresponding to a new LDPC parity check matrix with the enlarged codeword length of 2*1296.

4. The method of claim 3, wherein a permutation value at a location (i, j) in a new LDPC parity check matrix for the enlarged codeword length is 2*Pᵢⱼ+δᵢⱼ, with Pᵢⱼ denoting a value from the existing LDPC parity check matrix with L=1296 at a location (i, j) and with δᵢⱼ having a value of 0 or 1.

5. The method of claim 2, wherein, for L=1944 with a submatrix size Z=81, the encoding further comprises encoding with an enlarged submatrix size of 2*81=162 corresponding to a new LDPC parity check matrix with the enlarged codeword length of 2*1944.

6. The method of claim 5, wherein a permutation value at a location (i, j) in a new LDPC parity check matrix for the enlarged codeword length is 2*Pᵢⱼ+δᵢⱼ, with Pᵢⱼ denoting a value from the existing LDPC parity check matrix with L=1944 at a location (i, j) and with δᵢⱼ having a value of 0 or 1.

7. The method of claim 2, wherein, responsive to the enlarged codeword length=2*1296, the encoding comprises encoding using a coding rate R=½ with a submatrix size Z=2*54=108.

8. The method of claim 2, wherein, responsive to the enlarged codeword length=2*1296, the encoding comprises encoding using a coding rate R=⅔ with a submatrix size Z=2*54=108.

9. The method of claim 2, wherein, responsive to the enlarged codeword length=2*1296, the encoding comprises encoding using a coding rate R=¾ with a submatrix size Z=2*54=108.

10. The method of claim 2, wherein, responsive to the enlarged codeword length=2*1296, the encoding comprises encoding using a coding rate R=⅚ with a submatrix size Z=2*54=108.

11. The method of claim 2, wherein, responsive to the enlarged codeword length=2*1944, the encoding comprises encoding using a coding rate R=½ with a submatrix size Z=2*81=162.

12. The method of claim 2, wherein, responsive to the enlarged codeword length=2*1944, the encoding comprises encoding using a coding rate R=⅔ with a submatrix size Z=2*81=162.

13. The method of claim 2, wherein, responsive to the enlarged codeword length=2*1944, the encoding comprises encoding using a coding rate R=¾ with a submatrix size Z=2*81=162.

14. The method of claim 2, wherein, responsive to the enlarged codeword length=2*1944, the encoding comprises encoding using a coding rate R=⅚ with a submatrix size Z=2*81=162.

15. The method of claim 2, wherein, responsive to the enlarged codeword length=2*1944, the encoding comprises encoding using a coding rate R=½ and applying a lifting matrix to the existing LDPC parity check matrix, and wherein each element in the lifting matrix acting on a Z×Z cyclic permutation matrix Pi at a same location in an LDPC parity check matrix creates a submatrix of size 2Z×2Z such that:
a non-blank element “0” in the lifting matrix acting on the Z×Z cyclic permutation matrix Pi at the same location creates the 2Z×2Z submatrix with a value of an original element of the Z×Z cyclic permutation matrix disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix,
a non-blank element “1” in the lifting matrix acting on the Z×Z cyclic permutation matrix Pi at the same location creates the 2Z×2Z submatrix with the value of the original element of the Z×Z cyclic permutation matrix disposed along another diagonal line from an upper-right corner to a lower-left corner of the 2Z×2Z submatrix, while the value “−1” is duplicated and disposed along an opposite diagonal line from an upper-left corner to a lower-right corner of the 2Z×2Z submatrix, and
a non-blank element “−1” in the lifting matrix acting on the Z×Z cyclic permutation matrix Pi at the same location creates the 2Z×2Z submatrix with the value “−1” duplicated and disposed in the four corners of the 2Z×2Z submatrix.

16. The method of claim 2, wherein, responsive to the enlarged codeword length=2*1944, the encoding comprises encoding using a coding rate R=⅔ and applying a lifting matrix to the existing LDPC parity check matrix, and wherein each element in the lifting matrix acting on a Z×Z cyclic permutation matrix Pi at a same location in an LDPC parity check matrix creates a submatrix of size 2Z×2Z such that:
a non-blank element “0” in the lifting matrix acting on the Z×Z cyclic permutation matrix Pi at the same location creates the 2Z×2Z submatrix with a value of an original element of the Z x Z cyclic permutation matrix disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix, a non-blank element “1” in the lifting matrix acting on the Z×Z cyclic permutation matrix Pi at the same location creates the 2Z×2Z submatrix with the value of the original element of the Z×Z cyclic permutation matrix disposed along another diagonal line from an upper-right corner to a lower-left corner of the 2Z×2Z submatrix, while the value “−1” is duplicated and disposed along an opposite diagonal line from an upper-left corner to a lower-right corner of the 2Z×2Z submatrix, and
a non-blank element “−1” in the lifting matrix acting on the Z×Z cyclic permutation matrix Pi at the same location creates the 2Z×2Z submatrix with the value “−1” duplicated and disposed in the four corners of the 2Z×2Z submatrix.

17. The method of claim 2, wherein, responsive to the enlarged codeword length=2*1944, the encoding comprises encoding using a coding rate R=¾ and applying a lifting matrix to the existing LDPC parity check matrix, and wherein each element in the lifting matrix acting on a Z×Z cyclic permutation matrix Pi at a same location in an LDPC parity check matrix creates a submatrix of size 2Z×2Z such that:
a non-blank element “0” in the lifting matrix acting on the Z×Z cyclic permutation matrix Pi at the same location creates the 2Z×2Z submatrix with a value of an original element of the Z x Z cyclic permutation matrix disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix, a non-blank element “1” in the lifting matrix acting on the Z×Z cyclic permutation matrix Pi at the same location creates the 2Z×2Z submatrix with the value of the original element of the Z×Z cyclic permutation matrix disposed along another diagonal line from an upper-right corner to a lower-left corner of the 2Z×2Z submatrix, while the value “−1” is duplicated and disposed along an opposite diagonal line from an upper-left corner to a lower-right corner of the 2Z×2Z submatrix, and
a non-blank element “−1” in the lifting matrix acting on the Z×Z cyclic permutation matrix Pi at the same location creates the 2Z×2Z submatrix with the value “−1” duplicated and disposed in the four corners of the 2Z×2Z submatrix.

18. The method of claim 2, wherein, responsive to the enlarged codeword length=2*1944, the encoding comprises encoding using a coding rate R=⅚ and applying a lifting matrix to the existing LDPC parity check matrix, and wherein each element in the lifting matrix acting on a Z×Z cyclic permutation matrix Pi at a same location in an LDPC parity check matrix creates a submatrix of size 2Z×2Z such that:
a non-blank element “0” in the lifting matrix acting on the Z×Z cyclic permutation matrix Pi at the same location creates the 2Z×2Z submatrix with a value of an original element of the Z×Z cyclic permutation matrix disposed along a diagonal line from an upper-left corner to a lower-right corner of the 2Z×2Z submatrix, while a value “−1” is duplicated and disposed along an opposite diagonal line from an upper-right corner to a lower-left corner of the 2Z×2Z submatrix, a non-blank element “1” in the lifting matrix acting on the Z×Z cyclic permutation matrix Pi at the same location creates the 2Z×2Z submatrix with the value of the original element of the Z×Z cyclic permutation matrix disposed along another diagonal line from an upper-right corner to a lower-left corner of the 2Z×2Z submatrix, while the value “−1” is duplicated and disposed along an opposite diagonal line from an upper-left corner to a lower-right corner of the 2Z×2Z submatrix, and
a non-blank element “−1” in the lifting matrix acting on the Z×Z cyclic permutation matrix Pi at the same location creates the 2Z×2Z submatrix with the value “−1” duplicated and disposed in the four corners of the 2Z×2Z submatrix.

19. An apparatus, comprising:
a transceiver configured to communicate wirelessly; and
a processor coupled to the transceiver and configured to perform operations comprising:
encoding a plurality of bits with an enlarged codeword length which is longer than that of an existing low-density parity-check (LDPC) parity check matrix; and
communicating, via the transceiver, with the encoded plurality of bits in a wireless communication system.

20. The apparatus of claim 19, wherein the encoding comprises increasing a codeword length L by two times (2×) such that:
for L=1296, the enlarged codeword length=2*1296=2592, and for L=1944, the enlarged codeword length=2*1944=3888.
